(19) United States
(12) Patent Application Publication
(10) Pub. No.: US 2026/0223323 A1
(43) Pub. Date: Jul. 30, 2026

(54) MICRO-AXIAL PUMP HAVING ASYMMETRICAL STATOR TEETH

(71) Applicant: HEWLETT PACKARD ENTERPRISE DEVELOPMENT LP, Spring, TX (US)

(72) Inventors: Laura Sofia Lester, Spring, TX (US); John P. Franz, Tomball, TX (US); Ernesto Juan Ferrer, Aguadilla (PR)

(21) Appl. No.: 19/041,296

(22) Filed: Jan. 30, 2025

(51) Int. Cl. H05K 7/20; F04D 3/00; F04D 29/18; H02K 16/04

(52) U.S. Cl. CPC H05K 7/20272; F04D 3/00; F04D 29/181; H02K 16/04; H05K 7/20254; H05K 7/20772

(57) ABSTRACT

An axial pump for delivering liquid coolant to cool an electronic device comprises a conduit, an impeller in the conduit, a shaft, a rotor, and a stator. The conduit defines a flow path from an inlet of the conduit to an outlet of the conduit. The rotor is disposed in a hollow interior of the impeller and is rotatably coupled to the shaft. The stator is configured to drive rotation of the rotor about the shaft, with the impeller rotating along with the rotor about an axis of rotation extending parallel to the flow path. The stator comprises teeth that are heterogenous in shape, resulting in an asymmetrical stator, and reducing magnetic sticking of the rotor when powered off. A set of first stator teeth has a first profile shape and a set of second stator teeth have a second profile shape.

### INTRODUCTION

Some information processing systems utilize liquid cooling techniques to remove heat from the system. In these systems, a liquid coolant is circulated in a loop through the information processing devices (e.g., servers, networking devices, etc.) of the system, and heat generating components thereof (e.g., processors) are thermally coupled (e.g., via cold plates) to the liquid coolant so that the liquid coolant absorbs heat from these components. As the now-heated coolant exits the information processing devices, it carries the heat to a cooling device (such as a heat exchanger) which cools the liquid back to a desired operating temperature, whereupon the cooled liquid is circulated through the loop once again, extracting more heat from the information processing devices. Such a liquid cooling loop uses one or more pumps to drive the circulation of the liquid through the loop. Often, these pumps are disposed in a so-called coolant distribution unit (CDU) that provides a centralized pumping unit to circulates the liquid collectively through multiple information processing devices (e.g., an entire rack, or multiple racks, of such devices). These pumps are usually very large, with the CDU often taking up a substantial portion of a rack, or in some cases a full rack.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operations. In the drawings:

FIG. 1 is a schematic diagram illustrating a top view of an example pump.

FIG. 2 is a perspective view of another example pump.

FIG. 3 is an exploded view of the pump of FIG. 2.

FIG. 4 is an exploded perspective view of an impeller chamber subassembly of the pump of FIG. 2, including a perspective sectional view of a portion of the impeller chamber subassembly with the section taken along the plane 4-4 indicated in FIG. 2.

FIG. 5 is a cross-section of the pump of FIG. 2, with the section taken along the plane 4-4 indicated in FIG. 2.

FIG. 6 is a cross-section of a portion of the pump of FIG. 2 including a stator, a conduit, and impeller/rotor subassembly, with the section taken along the plane 6-6 indicated in FIG. 2.

FIG. 7 is a cross-section of a portion of the pump of FIG. 2 including a stator core, with the section taken along the plane 6-6 indicated in FIG. 2.

FIG. 8 is a cross-section of an alternative stator which may be used in the pump of FIG. 2.

FIG. 9 is a cross-section of another alternative stator which may be used in the pump of FIG. 2.

FIG. 10 is a cross-section of another alternative stator which may be used in the pump of FIG. 2.

FIG. 11 is a cross-section of another alternative stator which may be used in the pump of FIG. 2.

FIG. 12 is a schematic diagram of an information processing system with a pump.

### DETAILED DESCRIPTION

In some cases, it may be desired to utilize relatively small pumps in liquid cooling loops, rather than the commonly used large CDU pumps. One advantage of using smaller pumps for liquid cooling information processing systems is that the smaller pumps can be more efficient than the larger pumps, in terms of the amount of liquid they can move per unit of energy spent. The smaller pumps can also fit in places that the large pumps will not, which opens opportunities for system designers to arrange their systems in new and potentially more efficient ways which would not have otherwise been possible. For example, smaller pumps can allow for a distributed pumping architecture to be utilized, in which each information processing device is provided with one or more small pumps localized to the device (e.g., disposed within, or adjacent to, the chassis of the device) to control the circulation of fluid locally through that device in an individualized manner, rather than using a single large centralized pumping unit to control the flow of fluid collectively through all the devices in a rack or multiple racks. This distributed approach can improve efficiency and performance of the liquid cooling loop, potentially reducing power usage and noise while also delivering more coolant flow (and hence better cooling). In addition, this may also facilitate greater modularity and scalability of the system, as the pumping capacity of the system naturally scales along with the demand for cooling, since each new device added to the system brings its own pump(s) with it.

While having smaller pumps can in theory be advantageous, realizing these advantages can be challenging with existing pump technologies. Many existing pumps that can produce the needed levels of pressure and liquid flow rates for liquid cooling an information processing device are simply too large, or are too awkwardly shaped, to fit well within the densely packed environment of an information processing device. Other pumps (such as artificial heart pumps) may be small enough to fit in a space-constrained information processing system, but these generally have inadequate pumping characteristics (e.g., insufficient pressure, insufficient flow rates, poor efficiency, etc.) for the liquid cooling context. In other words, it is challenging to find pumps which both have a suitable small form factor and which have desired pumping characteristics.

Thus, to meet this unique combination of challenges, specialized pumps are being developed, such as the micro-axial pumps described in U.S. Pat. No. 11,015,608 B2, the contents of which are incorporated herein by reference in their entirety. An axial pump has an impeller (the part that moves within the liquid to drive the flow) that spins along an axis that is coaxial with a flow direction of the liquid, in contrast to centrifugal pumps which have impellers that spin along an axis transverse to the flow direction of the liquid. In addition, in certain micro-axial pumps such as those disclosed in U.S. Pat. No. 11,015,608 B2, the rotor (the part which is magnetically driven to rotate) is attached directly to the impeller forming a rotor/impeller assembly which is entirely disposed within the fluid channel, as opposed to having a rotor sitting outside of the fluid channel with a shaft piercing through a wall of the channel and connecting the rotor to the impeller. A stator sitting outside the fluid channel generates magnetic fields in response to receiving electrical driving current, these magnetic fields interact with permanent magnets in the rotor to generate a torque on the impeller/rotor assembly which causes it to spin, and blades extending along the exterior of the spinning impeller push liquid through the pump. The axial arrangement, together with various other improvements, allows for the micro-axial pumps to have a form factor which is both extremely small and conveniently shaped (e.g., rectangular in cross-section), while still providing the same or better effectiveness and efficiency as larger pumps. For example, some micro-axial pumps under development may be similar in size and shape to a deck of cards while being capable of providing flow rates of such as 4 GPM at 4PSID, 2 GPM at 11.5 PSID, or 1 GPM at 13.9 PSID (PSID refers to a pressure drop in pounds per square inch).

However, the size and form factor of such micro-axial pumps can pose a variety of technical challenges. For example, a stator and rotor arrangement of some micro-axial pumps can lead to the pump being susceptible to its impeller/rotor assembly becoming magnetically stuck when powered off. When the rotor is magnetically stuck, the stator is unable to generate a torque strong enough to cause the rotor to begin rotating, and thus the rotor remains stationary. The cause of this phenomenon will be explained in greater detail below.

Various forces, such as friction, resist the rotation of the impeller/rotor assembly, and therefore to get a rotor started spinning the stator must supply a torque that exceeds some minimum torque threshold. The amount of torque that the stator can apply at any given moment varies depending on the orientation of the rotor and the amount of current supplied to the stator. In certain orientations of the rotor, the stator applies zero torque to the rotor even if relatively large amounts of electrical current are applied, and in a small range around these zero-torque points the maximum torque the stator can apply, given a reasonable supply of electrical current, is less than the minimum torque threshold. Consequently, if the rotor comes to a stop within one of these low-torque ranges when the pump is powered off, then when the pump is next powered on, it may not be possible for the pump to move the rotor out of that orientation, i.e., the rotor will be stuck.

Furthermore, in some micro-axial pumps, the configuration of the stator and rotor make it very likely that the rotor will come to rest in one of the low-torque ranges. The magnets of the rotor continue to magnetically interact with the stator to some degree even when electrical power is not supplied, which interaction can generate a small torque on the rotor referred to as a “cogging torque.” The magnitude of this cogging torque varies depending on the orientation of the rotor, with it being non-zero in most orientations and zero at certain orientations. Orientations at which the cogging torque is non-zero tend to be unstable, meaning that the cogging torque tends to repel the rotor from these orientations. On the other hand, the orientations at which the cogging torque is zero tend to be stable, meaning that the rotor can stay in one of these orientations indefinitely, absent some external intervention. These orientations may thus be referred to herein as stable no-power orientations because they become the stable orientation for the rotor when no electrical power is applied to the stator, i.e., when the pump is powered off. Because these orientations are stable while other orientations are unstable, the rotor is likely to come to rest in one of these stable no-power orientations when the pump is powered off. In some micro-axial pumps, at least some of the stable no-power orientations also happen to fall within the above-described low-torque ranges. As a result, when the pump is turned off, there is a high likelihood that the rotor will come to rest within one of the low-torque ranges, resulting in the rotor becoming stuck.

In some micro-axial pumps, the tendency for the stable no-power orientations to fall within the low-torque ranges results from the particular stator/rotor configurations of these pumps, which arise from the small size and form factor of the pump. Furthermore, in certain micro-axial pumps, the impeller/rotor assembly is disposed in the fluid channel of the pump and the stator is on the outside of the fluid channel, such that the wall of the fluid channel, the wall of the impeller, and the volume containing the liquid are all positioned between the stator and the rotor. This results in there being a relatively large “air gap” between the stator teeth and the permanent magnets of the rotor (the term “air gap” is commonly used in the art to describe the gap between stator and rotor, although there may be substances other than air in the gap). This large air gap may result in the low-torque ranges being wider than they otherwise would be, which makes it more likely that one of the stable no-power orientations will fall within one of the low-torque ranges.

To address these and other challenges, example micro-axial pumps disclosed herein comprise a stator having stator teeth which are heterogenous in shape and configured to avoid magnetic sticking of the rotor. The stator teeth include first stator teeth having a first profile shape and second stator teeth having a second profile shape, which is different than the first profile shape. As a result of these different tooth shapes, the profile of the stator as a whole is asymmetrical (about certain planes, as described in more detail below). This asymmetrical stator arrangement with heterogeneously shaped stator teeth causes the stable no-power orientations to shift relative to the low torque ranges (or vice versa) such that the stable no-power orientations no longer fall within any of the low torque ranges. Thus, when the pump is powered off, the rotor is likely to come to rest outside of a low-torque range and therefore when power is later returned the stator will be able to supply enough torque to overcome resistance and get the rotor moving. In other words, the pump is very unlikely to become magnetically stuck.

An additional advantage provided by the shifting of the stable no-power orientations is that it may be easier for the pump to determine, at startup, which flow direction should be used for electricity being supplied to the stator. During operation, the flow direction of the electrical current needs to be periodically changed depending on the orientation of the rotor to ensure that the magnetic fields being generated by the stator continue to drive, rather than oppose, the rotation of the rotor. Thus a magnetic sensor (e.g., a Hall-effect sensor) may be included in the pump to allow the pump controller to determine the present orientation of the rotor and, based on this, determine the proper direction in which to supply the current. However, due to how magnetic sensors work, it is possible that for some orientations of the rotor the sensor output is ambiguous, i.e., the sensor output is consistent with two different orientations. If one of these ambiguous sensor outputs is generated when the rotor is already spinning, the pump controller can resolve the ambiguity and deduce which one of the possible orientations the rotor is actually in because the controller also knows the recent history of previous orientations of the rotor. However, if the rotor is in one of the orientations that generates an ambiguous sensor output at startup, the pump controller cannot easily deduce which one of the possible orientations the rotor is in because there is no history of previous orientations to consult. Thus, if the rotor is in an ambiguous orientation at startup, the pump controller may not know which direction to apply current in order to get the rotor started moving. This problem can be exacerbated in some micro-axial pumps because the orientations of the rotor which are ambiguous to the magnetic sensor may correspond to the stable no-power orientations of the rotor, making it likely that the rotor will stop in an ambiguous orientation when power is removed, making it difficult to determine the current direction upon next startup.

However, in examples disclosed herein, the stator shape results in the stable no-power orientations being shifted so that they no longer coincide with the orientations that generate ambiguous sensor outputs. Consequently, when power is removed, the rotor is likely to come to rest in an orientation in which the sensor output is not ambiguous, and therefore when the pump is next started up again, the controller can easily determine the direction of driving current.

Turning now to the figures, various devices, systems, and methods in accordance with nonlimiting aspects of the present disclosure will be described.

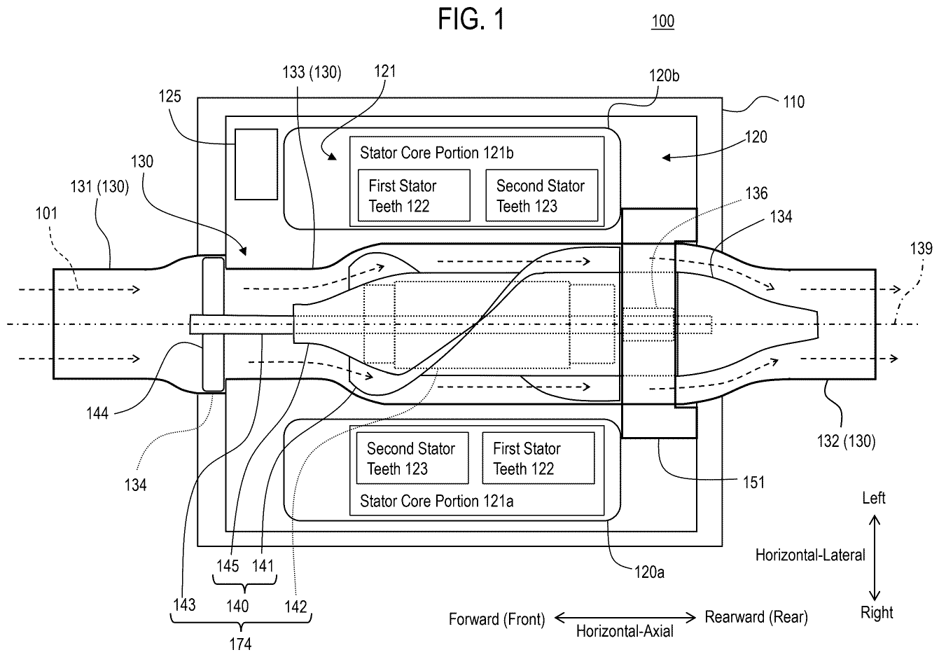

FIG. 1 is a schematic diagram conceptually illustrating a pump 100. FIG. 1 shows the pump 100 from a perspective above the pump and illustrates functional and some general positional relationships between components, as described below, but the diagram is schematic in nature and is not intended to illustrate specific shapes, dimensions, or other structural details accurately or to scale. It should be understood that implementations of the pump 100 can vary from one another in various aspects. Some implementations of the pump 100 may have different numbers and arrangements of the illustrated components. Some implementations of the pump 100 may include other parts that are not illustrated in FIG. 1. Some implementations of the pump 100 may omit one or more of the parts that are illustrated in FIG. 1.

As shown in FIG. 1, the pump 100 comprises a housing 110, a stator 120 (also “motor stator 120”), control circuitry 125, a conduit 130 defining a liquid flow path 101, and an impeller/rotor sub-assembly 174 comprising an impeller 140, a rotor 142, and a shaft 143. The housing 110 and conduit 130 are shown as transparent to allow visibility of the other components. In addition, some parts (or portions of parts) which are covered by (e.g., contained within) other parts are shown in dotted lines; this is done to make it easier to visually distinguish the covered parts from the covering parts. The components of the pump 100 will be described in greater detail below.

The housing 110 comprises one or more walls or other support structures that support and at least partially enclose or house some of the other components of the pump 100. The housing 110 may be a single part or made from multiple parts assembled together. In some examples, the parts of the housing 110 may also be coupled to and/or form an integral part of the other parts of the pump 100. For example, portions of the conduit 130 may also form parts of the housing 110.

The conduit 130 comprises walls that partially enclose a volume and define the liquid flow path 101 through that volume, with the liquid flow path 101 being the path along which liquid coolant (e.g., water or other coolants) flows as it traverses the pump 100. The conduit 130 comprises a pump inlet portion 131 (also “inlet 131”) having a first opening into the enclosed volume of the conduit 130, a pump outlet portion 132 (also “outlet 132”) having a second opening into the enclosed volume of the conduit 130, and an impeller chamber portion 133 between the other two portions 131/132. The impeller chamber portion 133 houses the impeller 140 and is fluidically coupled to the inlet 131 and outlet 132. The pump inlet portion 131 and pump outlet portion 132 may comprise structures for fluidically coupling the pump with coolant lines of a liquid cooling loop, such as hose barbs, fittings, quick connect couplings, and/or other liquid coupling mechanisms as would be familiar to those of ordinary skill in the art. The conduit 130 may be liquid tight, sealing the interior volume from an exterior environment, other than at openings in the inlet 131 and outlet 132 that allow the enclosed interior volume to be fluidically coupled to the exterior environment (e.g., to coolant lines of a liquid cooling loop). In some examples, the inlet 131 and outlet 132 may extend outside of the housing 110 of the pump 100. In some examples, the impeller chamber portion 133 is contained within the housing 110.

The conduit 130 has a central longitudinal axis. This axis is coaxial with various other axes of other parts of the pump 100, including a rotational axis of the rotor 142, a rotational axis of the impeller 140 (described below), and a central longitudinal axis of a shaft 143, and therefore all of these axes are depicted in FIG. 1 by the same axis 139. Accordingly, all of these co-axial axes may hereinafter be referred to interchangeably as the axis 139. Liquid flowing through the conduit 130 flows, as whole, along directions parallel to the axis 139, as indicated by the dashed arrows representing the flow path 101 in FIG. 1. Note that the liquid may also spiral circumferentially around the axis 139 (in addition to moving axially) while traversing certain portions of the flow path 101 (e.g., while passing the impeller 140), but the bulk or average motion of the liquid as a whole in traversing the conduit 130 is along directions parallel to the axis 139. The liquid flow path 101 is shown in FIG. 1 to illustrate how the pump 100 is configured to flow liquid when deployed, but note that the liquid is not necessarily part of the pump 100 and is not necessarily present in all states of the pump 100. For example, prior to being deployed in a liquid cooling loop, there might be no liquid in the pump 100.

As mentioned above, the impeller/rotor sub-assembly 174 comprises an impeller 140 and a rotor 142 attached together and disposed within the conduit 130. The impeller/rotor sub-assembly 174 also comprises a shaft 143 to which rotor 142 is rotatably attached such that the rotor 142, and the impeller 140 coupled thereto, can rotate about the shaft 143. A rotation axis of the rotor 142, a rotation axis of the impeller 140, a longitudinal axis of the shaft 143, and a longitudinal axis of the conduit 130, are all coaxial, as mentioned above. The shaft 143 is fixedly attached to the housing 110, and thus when the rotor 142 and impeller 140 rotate about the shaft 143, they are also rotating relative to the housing 110. The impeller 140 and the rotor 142 will be described in greater detail in turn below.

The impeller 140 is housed within the conduit 130, specifically in the impeller chamber 133 thereof. The impeller 140 is configured to, when rotated about the axis 139, drive liquid to flow along the flow path 101 through the conduit 130. The impeller 140 comprises an impeller body 145 and blades 141 that protrude radially from and spiral along/around the impeller body 145. References to the blades 141 spiraling along or around the impeller body 145 mean that the blades 145 extend along paths that axially traverse the impeller body 145 while simultaneously circling circumferentially around the impeller body 145 through at least portions of the path; for example, the paths could be helical. The blades 141 are configured to force the liquid axially along the flow path 101 through the conduit 130 as the impeller 140 rotates.

The impeller body 145 is hollow (i.e., has an internal bore therethrough) and the rotor 142 is at least partially contained within the hollow interior of the impeller 140. Specifically, the impeller body 145 may have a shape roughly of a hollow cylinder with openings at both ends and with one end being tapered/rounded. The shaft 143 also extends through the internal bore of the impeller body 145.

In some examples, the impeller body 145 and the impeller blades 141 are integrally connected, meaning they are formed together as two parts of the same monolithic body. The impeller body 145 may be formed from any solid material which can be formed into the desired shape. For example, the impeller body 145 may be formed from various plastics, which can be formed into the desired shape by injection molding, additive manufacturing (e.g., 3D printing), or other techniques. As another example, the impeller body 145 may be formed from various metals, which can be formed into the desired shape by casting, additive manufacturing (e.g., 3D printing), or other techniques.

The rotor 142 comprises magnetic portions (e.g., permanent magnets) and bearings, which are coupled together such that the bearings support the magnetic portions. The bearings are in turn rotatably coupled to the shaft 143 such that the rotor 142 can rotate about the shaft 143. Specifically, the magnetic portions of the rotor 142 are arranged to interact with magnetic fields generated by the stator 120 (which will be described below) to produce rotation of the rotor 142. The rotor 142 is disposed within and attached to the impeller body 145 (e.g., by press-fitting, adhesive, or other means), such that the rotation of the rotor 142 causing the impeller 140 attached thereto to also rotate. Thus, the rotor 142 and the stator 120 may together form an electromagnetic motor. The magnetic portions may comprise permanent magnets and/or magnetically attractable (e.g., ferromagnetic) materials (e.g., iron, steel, etc.) which are capable of interacting with (e.g., being attracted or repelled by) the generated magnetic fields. In some examples, the magnetic portions comprise multiple permanent magnets which are distributed circumferentially around the axis 139 and arranged with alternating polarities.

As shown in FIG. 1, the shaft 143 is secured to the conduit 130 and housing 110 via a front support 144 and a rear support 151. The front support 144 engages and holds a front portion of the shaft 143 and is coupled to the walls of the conduit 130. The rear support 151 engages and holds a rear portion of the shaft 143 and is also coupled to the walls of the conduit 130. Front and rear are used herein in relation to the orientation of the pump 100 illustrated in FIG. 1, with the inlet side being the “front” side and the outlet side being the “rear” side. However, these terms are meant merely to aid understanding and are not limiting. In particular, in some examples of the pump 100, the supports 144 and 151 could be reversed in orientation, with the support 144 being nearer the outlet 132 and the support 151 being nearer the inlet 131, in which case the terms “front” and “rear” as used herein would be reversed in relation to these components.

In some examples, the pump 100 further comprises an adjustment mechanism 136. The adjustment mechanism 136 couples the shaft 143 to the rear support 151. The adjustment mechanism 136 is actuatable, and when actuated changes the position of the shaft 143 relative to the rear support 151, and hence also relative to the impeller chamber 133. More specifically, the adjustment mechanism 136 is configured to cause translation along the rotation axis 139 of the rear end of the shaft 143 relative to the rear support 151, which in turn causes translation of the front end of the shaft 143 relative to the front support 144. Because the shaft 143 is coupled to the rotor 132 and the rotor 132 is coupled to the impeller 140, when the shaft 143 is translated along the axis 139 this also causes the impeller 140 to be translated along the axis 139 relative to conduit 130. Adjusting the position of the impeller 140 in this manner can change the clearance between the blades 141 and the walls of the conduit 130, particularly near the front end of the impeller 140. This can allow for smaller clearances to be obtained between the blades 141 and conduit 130, which improves performance, without requiring high precision in the parts which would inordinately increase costs. The adjustment mechanism 136 may include, in some examples, any of the adjustment mechanisms described in U.S. patent application Ser. No. 17/977,200 entitled “AXIAL PUMP WITH ADJUSTABLE IMPELLER” and filed on Oct. 31 2022, the entire contents of which is incorporated herein by reference.

The stator 120 is configured to receive electrical power from the control circuitry 125 and in response generate alternating magnetic fields that interact with the rotor 142 of the impeller/rotor sub-assembly 174 to cause the rotor 142 (and hence the impeller 140 coupled thereto) to rotate about a rotation axis thereof, depicted in FIG. 1 as axis 139. The stator 120 may comprise wire windings (not illustrated) wound around a stator core 121. The windings generate magnetic fields in response to electric current flowing therethrough. The stator core 121 extends and shapes the generated magnetic fields in the desired pattern around the conduit 130, such that the magnetic fields can drive rotation of the rotor 142. The stator core 120 is made from magnetically susceptible materials, which in some examples may be arranged in a laminated stack. The stator core 120 comprises a base portion around which the wire windings are wound and stator teeth protruding from the base portion. The stator teeth include a set of first stator teeth 121 and a set of second stator teeth 122.

As shown in FIG. 1, the stator 120 has a split stator design in which the stator 120 is split into a first stator portion 120a and a second stator portion 120b arranged on diametrically opposite lateral sides of the conduit 130. Each of these stator portions 120a and 120b comprises part of the stator core 121, i.e., the stator portion 120a comprises stator core portion 121a and the stator portion 120b comprises stator core portion 121b. Each of the stator core portions 120a and 120b comprises as least one first stator tooth 122 and at least one second stator tooth 123. The first stator teeth 122 have a first cross-sectional shape and the second stator teeth 123 have a second cross-sectional shape, different from the first cross-sectional shape.

More specifically, each of the first and second stator teeth 122/123 comprise a proximal portion which is coupled to the base of a stator core portion 120a/120b and extends away from the base towards the conduit 130, and a distal portion which is coupled to the proximal portion and which is disposed closest to the conduit 130. In some examples, the first stator teeth 122 may have differently shaped distal portions than the second stator teeth 123. In some examples, the distal portions of the first and second stator teeth 122/123 may be generally similar to one another in profile shape, but they may have certain key differences which will be described below.

In particular, in some examples, the distal portion of each stator tooth 122/123 are similar to one another in that they each may have a general shape of a curvilinear triangle. However, certain aspects of the generally curvilinear triangle shape of the distal portions of the first stator teeth 122 may differ from aspects of the generally curvilinear triangle shape of the distal portions of the second stator teeth 123. A curvilinear triangle is a three-sided shape like a triangle except that one of the edges is curved rather than straight. Specifically, in some examples, the distal portion of each stator tooth 122/123 may have a vertically extending straight edge (“vertical edge”), a horizontally extending straight edge (“horizontal edge”) connected to the vertical edge, and a concave curved edge extending between the other two edges and facing the rotor. The concave curved edge may be the edge closest to the conduit 130. The distal portion of the tooth 122/123 may be joined to the proximal portion of the tooth 122/123 at a corner where the vertical and horizontal straight edges meet.

In some examples, the profile shapes of the first and second teeth 122/123 differ from one another in that one or more edges and/or corners of the distal portions of the second stator teeth 123 may be different (e.g., in length, curvature, profile, etc.) than the corresponding edge or corner in the distal portion of the first stator teeth 122. These first and second stator teeth 122/123 are arranged circumferentially around the outside of the fluid chamber 130 of the pump 100, alternating between the first stator teeth 122 and second stator teeth 123. In some examples, each first stator tooth 122 is arranged diametrically opposite from another first stator tooth 122, and similarly each second stator tooth 123 is arranged diametrically opposite from another second stator tooth 123. In some examples, there are four stator teeth, including two first stator teeth 122 and two second stator teeth 123, with one of each of the first and second stator teeth 122/123 being arranged in each of the stator core portions 121a/121b.

In some examples, the aforementioned differences between the first and second teeth 122/123 includes a difference in an edge length of one of the straight edges, which results in the distal portions of the first stator teeth 122 and the second stator teeth 123 having different aspect ratios than one another. In this context, aspect ratio refers to the ratio of the length of the vertical edge of a tooth 122/123 to the length of the horizontal edge of the tooth 122/123. In some of these examples, the difference in aspect ratio results from the vertical edge in each second tooth 123 being shorter than the vertical edge in each first tooth 122. In other examples, the difference in aspect ratio results from the horizontal edge of each second tooth 123 being shorter than the horizontal edge in each first tooth 122.

As another example, in some implementations the curved edge of the first teeth 122 may differ in profile than the curved edge of the second teeth 123. The difference in profile between the respective curved edges of the first and second teeth 122/123 can include differences in the overall curvature of the curved edges and/or differences in the number or type of irregularities (e.g., cutouts) included in the curved edges. For instance, a difference in curvature of the curved edges may include, in some examples, the curved edges of the first teeth 122 tracing an arc corresponding to a portion of a circle centered at the rotational axis of the rotor, while the curved edges of the second teeth 123 trace an arc corresponding to a portion of an ellipse (with non-zero eccentricity) centered at the rotational axis. A difference in the number or type of irregularities included in the curved edges may include, for example, the curved edge of the first teeth 122 having no cutouts while the curved edge of the second teeth 123 has one or more cutouts.

In some examples, shapes of the distal portions of the first and second teeth 122 and 123 may differ from one another in both their aspect ratios and in the profiles of their curved edges. For example, in some implementations in which horizontal or vertical edges of the first teeth 122 have different lengths than the corresponding edges in the second teeth 123, the curvatures of the curved edge of the first and second teeth 122/123 may also differ from one another.

In some examples, one of the differences in shape between the distal portions of the first and second teeth may include differences between one or more corresponding corners at which the curved edge joints one of the straight edges. The curved edge may directly join with a straight edge in some cases, forming a sharp corner. In other cases, the curved edge does not directly join the straight edge and is instead joined indirectly with the straight edge via a small corner segment which extends therebetween, forming what is termed herein a “blunted corner.” In other words, a blunted corner has the shape that would result if a sharp corner of an ideal curvilinear triangle were cut off. Another way to conceptualize these corners is to consider their “corner height.” As used herein the “corner height” of a corner refers to the distance between the end point of the curved edge and the end point of the straight edge at the corner. In a sharp corner, the corner height is zero, while in a blunted corner, the corner height is non-zero. In some examples, the first teeth 122 may differ from the second teeth 123 in that they may have differing corner heights for corresponding ones of their blunted corners. In particular, in some examples, the first teeth 122 may differ from the second teeth 123 in that a given corner of the first teeth 121 may be blunted (positive corner height) while the corresponding corner in the second teeth 123 is sharp (zero corner height).

As mentioned above, the stators 120 of the example pumps 100 disclosed herein can shift the stable no-power orientations so that they fall outside of the low-torque ranges of the pump 100. In some examples, a starting torque of at least 2 mNm may be needed to reliably get the rotor moving. In some comparative micro-axial pumps whose stators do not have the improvements disclosed herein, when the rotor is stopped in a stable no-power orientation, only about 1 mNm of starting torque can be supplied to the rotor, assuming that 2 amps of electrical power is supplied, which is a desired operating current in these pumps. This is well short of the 2 mNm torque threshold needed to get the rotor moving. In contrast, in various example pumps 100 disclosed herein, which are configured the same as the comparative pumps mentioned above except that the stators 120 of the example pumps 100 include the improvements disclosed herein, when the rotor 142 is stopped in a stable no-power orientation, the stator 120 can generate torque well above the 2 mNm threshold when supplied with 2 amps, such as 5.65 mNm of starting torque in one implementation.

The control circuitry 125 is configured to control operations of the pump 100. In some examples the control circuitry 125 comprises a printed circuit assembly (PCA) with various electronic components formed therein and/or mounted thereon, and/or additional components external to the PCA. In some examples the control circuitry 125 includes logic to drive operations of the pump 100. For example, control circuitry 125 may include a microcontroller. As another example, the control circuitry 125 may include discrete logic circuits (digital or analog), in addition to or instead of a microcontroller. The control circuitry 125 may also include sensors, such as temperature sensors, electrical power usage sensors, moisture sensors (e.g., for leak detection), magnetic field (e.g., Hall effect) sensors, or other sensors. The control circuitry 125 may also include power delivery components, such as transistors or other switches (e.g., relays), capacitors, diodes, etc. In some examples, the control circuitry 125 may include communications components for communicating with outside devices such as a system controller, baseboard management controller (BMC), rack controller, etc., for example via the cables (not illustrated) coupled to the pump 100 and/or wirelessly (via, e.g., Bluetooth, WiFi, etc.). The control circuitry 125 may be electrically coupled to the stator 120 to provide electrical signals thereto to drive the operation of the stator 120. The control circuitry 125 may be coupled to an outside power source and/or an outside controller via wires or cables (not illustrated).

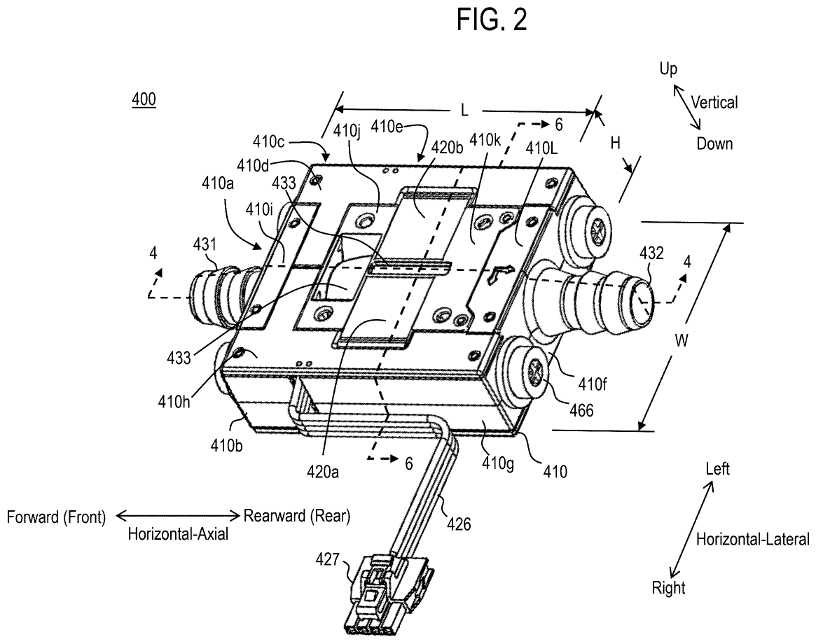

Turning now to FIGS. 2-7, another example pump will be described, in the form of pump 400. The pump 400 is an example implementation of the pump 100 described above. Thus, some components of the pump 400 are similar to (e.g., example implementations or configuration of) corresponding components already described above, and thus the descriptions of the components of the pump 100 above are applicable to the similar components of the pump 400, and duplicative descriptions of certain aspects of the pump 400 may thus be omitted. Corresponding components may be referred to using reference numbers having the same last two digits, such as 110 and 410. It should be understood that the pump 400 is but one possible implementation of the pump 100, and the pump 100 is not limited to the pump 400. Similarly, the individual components of the pump 400 are examples of the corresponding individual components of the pump 100, but the individual components of the pump 100 are not limited to the corresponding components of the pump 400.

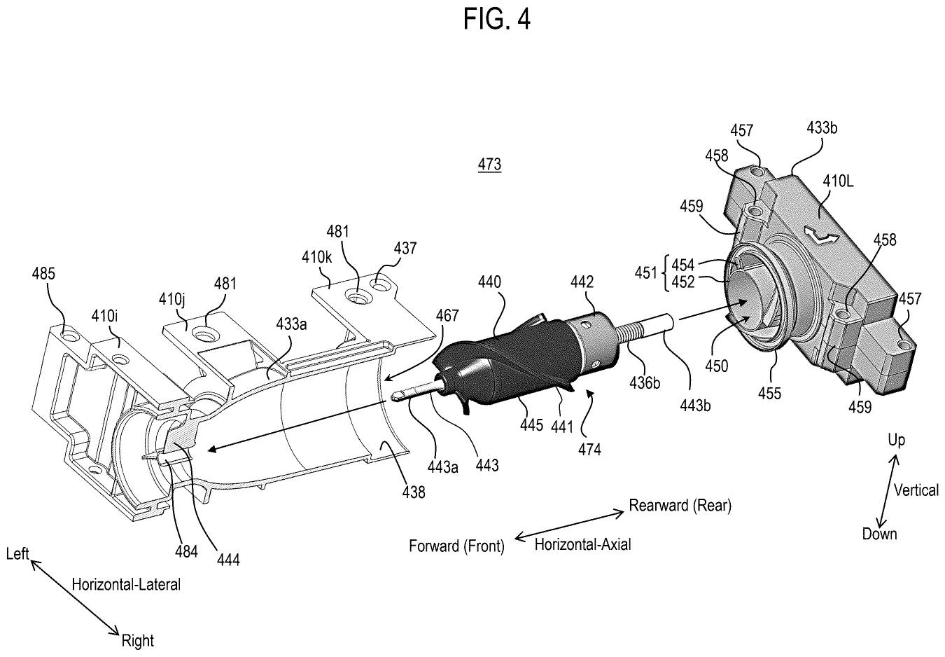

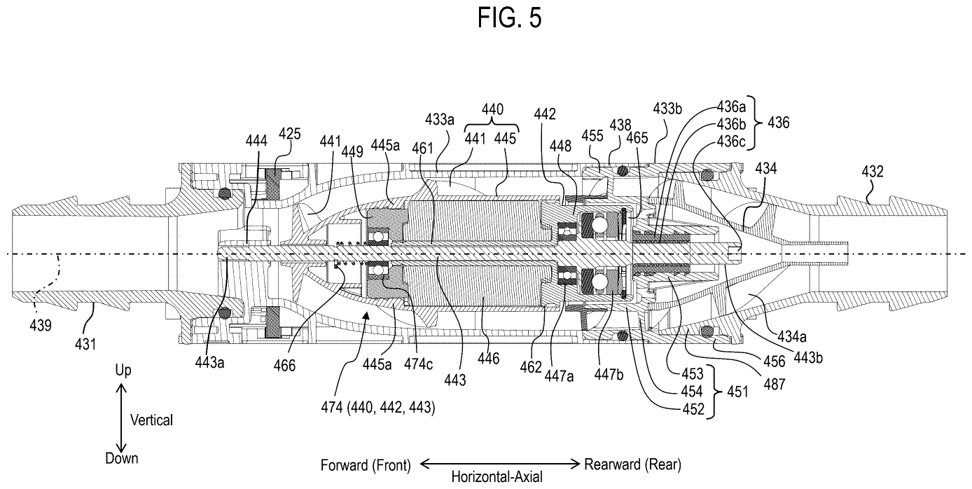

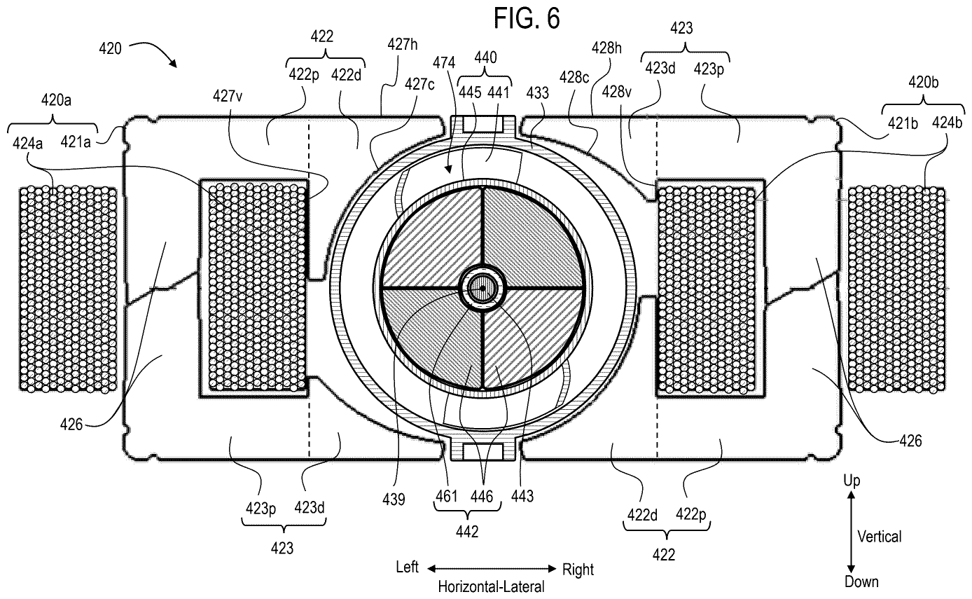

FIGS. 2, 3, and 5 show views of the full pump 400, including perspective, exploded, and longitudinal cross-sectional views, respectively. FIGS. 4, 6, and 7 show isolated portions of the pump 400 in various views. Specifically, FIG. 4 shows an impeller chamber subassembly 473 of the pump 400 in an exploded and partial cross-sectional view. FIG. 5 shows a stator 420, a impeller chamber 433, and an impeller/rotor subassembly in cross-sectional view. FIG. 6 shows a portion of a core of the stator 420 in an enlarged cross-sectional view.

The order in which components of the pump 400 are described below is chosen to aid in understanding the structural and functional relationships between the components. However, the logical order which best aids this understanding is not necessarily the same as the order in which the components appear in the drawings. Thus, FIGS. 2-7 will not be described in strict sequence below. Instead, as aspects of the pump are described, certain figures that are thought to be most helpful to understanding the particular aspect under discussion will be called out, even if that requires moving back and forth between the drawings out of order.

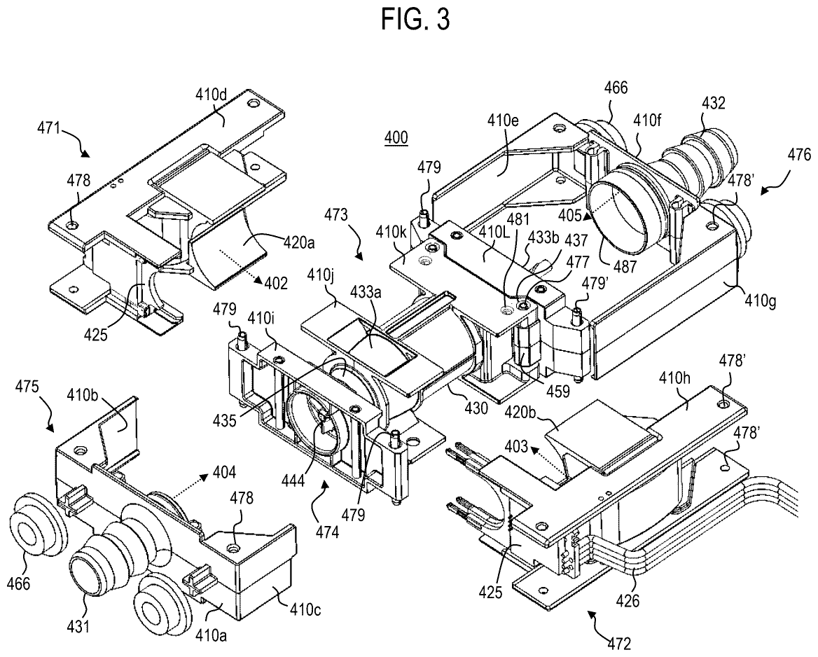

As shown in FIGS. 2 and 3, the pump 400 comprises a number of subassemblies, including a first stator subassembly 471, a second stator subassembly 472, an impeller chamber subassembly 473, an inlet subassembly 475, and an outlet subassembly 476. Each of these subassemblies will be described in greater detail below.

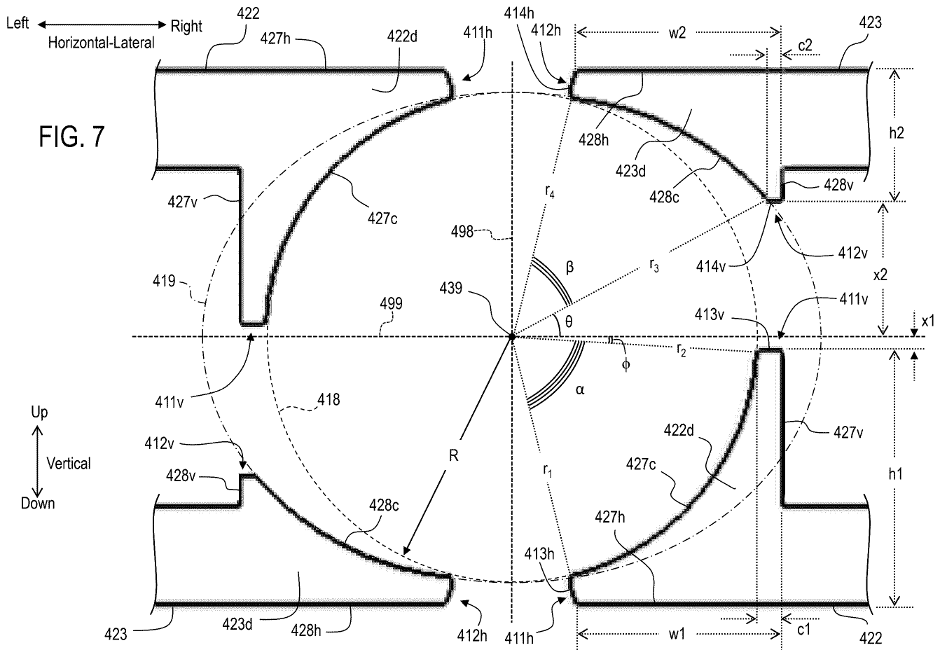

As shown in FIG. 3 the first and second stator subassemblies 471 and 472 comprise first and second stator portions 420a and 420b, respectively. In addition, the first and second stator subassemblies 471 and 472 comprise the PCBs 425, which make up a split PCA, such as the split PCA described in the U.S. patent application Ser. No. 17/976,406 entitled “AXIAL PUMP WITH SPLIT PRINTED CIRCUIT BOARD ASSEMBLY (PCA)” and filed on Oct. 28 2022, the entire contents of which is incorporated herein by reference. The PCBs 425 are electrically coupled, for example via solder or other electrical connections to the first and second stator portions 420a and 420b, respectively. As shown in FIG. 3, the first and second stator subassemblies 471 and 472 are positioned on opposite lateral sides of the impeller chamber subassembly 473. Thus, during assembly of the pump 400 the first and second stator subassemblies 471 and 472 may be positioned as shown in the exploded view of FIG. 3 and then the stator subassemblies 471 and 472 may be moved laterally (along directions indicated by arrows 402 and 403) to bring the stator subassemblies 471 and 472 together around the impeller chamber subassembly 473. Once so assembled, the stator portions 420a and 420b are positioned adjacent to and radially surround the impeller chamber 433 (except for small regions at the top and bottom of the impeller chamber 433, which are not surrounded), as shown in FIGS. 2 and 6. Moreover, as the first and second stator subassemblies 471 are coupled to the impeller chamber subassembly 473, the PCBs 425 become electrically coupled. The specific structure of the stator portions 420a and 420b will be described in greater detail below with reference to FIGS. 6 and 7 following the description of the other aspects of the pump 400.

Returning to FIGS. 3 and 4, the impeller chamber subassembly 473 comprises an impeller chamber 433 and an impeller/rotor subassembly 474 housed (at least partially) within the impeller chamber 433. The impeller chamber 433 comprises a front portion 433a and a rear portion 433b. The impeller chamber front portion 433a comprises a bore 467 and the rear portion 433b comprises a bore 450. As suggested by the arrows in FIG. 4 when the impeller chamber subassembly 473 is assembled the front portion 433a and rear portion 444b are coupled together with the impeller/rotor subassembly 474 positioned partially inside the bore 467 and partially inside the bore 450. As shown in FIG. 3, the impeller chamber front portion 433a comprises engagement portion 438, which defines a rear opening of the bore 467. As shown in FIG. 6, the impeller chamber rear portion 433b comprises an engagement portion 455 configured to engage with (e.g., be received within) the engagement portion 438 of the front portion 433a to couple the front portion 433a and rear portion 433b together. The engagement portion 455 encircles and defines the bore 450.

As shown in FIG. 4, the impeller/rotor subassembly 474 comprises an impeller 440 coupled to a rotor 442, which is in turn coupled to a shaft 443. The impeller 440 comprises an impeller body 445, blades 441 protruding radially from the impeller body 445 and spiraling axially and circumferentially along and around the outer surface of impeller body 445. The shaft 443 comprises a front end 443a and a rear end 443b.

As shown in FIG. 5, the rotor 442 comprises a bearing tower which includes a bearing tower shaft 461, a front bearing housing 449 attached to a front end of the bearing tower shaft 461, and a rear bearing housing 448 attached to a rear end of the bearing tower shaft 461. The rotor 442 also comprises magnets 446 which are distributed around the bearing tower shaft 461 and fixedly coupled to the bearing tower so as to move together with the bearing tower. The shaft 443 extends through an interior axial boar of the bearing tower shaft 461, as well as through a central bore 469c of the front bearing housing 449 and central openings in the front and rear radial bearings 447a and 447c and rear thrust bearing 447b. The bearing housings 448 and 449 each house bearings 447 that rotatably coupled the rotor 442 to the shaft 443. Specifically, as shown in FIG. 5, the front bearing housing 449 contains front radial bearings 447a that bear radially against the shaft 443, whereas the rear bearing housing 448 contains rear radial bearings 447b that bear radially against the shaft 443 and rear thrust bearings 447c that bear axially against a flange of the shaft 443. The front and rear bearing housings 449 and 448 may also engage with the magnets 446 to help secure the magnets 446 on the shaft 461. A spring clip retainer 465 may be inserted into the rear bearing housing 448 behind the thrust bearing 447b to retain the thrust bearing 447b in the housing 448. A clip 466 may be attached to the shaft 443 forward of the front bearing housing 449, and a spring may be disposed between the clip 466 and the front radial bearing 474c to hold the front radial bearings 447 in the bearing housing 449.

As show in FIG. 5, the rotor 442 (with the shaft 443 coupled thereto) is received within the impeller 440 and the impeller 440 is attached thereto (e.g., via press fitting, adhesives, or other means) to form the impeller/rotor subassembly 447. For example, the front bearing housing 449 may engage with an engagement portion 445a inside a central internal cavity of the impeller body 445 to attach the rotor 442 to the impeller 440. An example of an impeller/rotor subassembly which may be used as the impeller/rotor subassembly 474, as well as an example method of manufacturing such a subassembly, is described in U.S. patent application Ser. No. 18/930,262, the entire contents of which are incorporated herein by reference.

Once the impeller/rotor subassembly 474 is assembled, it may be inserted into the conduit 430 and the shaft 443 may be coupled to the conduit 430. Thus, as the impeller 440 rotates about the shaft 443 it also rotates relative to the conduit 430. As shown in FIGS. 4 and 5, when the impeller chamber subassembly 473 is assembled, the impeller 440 is contained within the impeller chamber 433, with a front end 443 of the shaft 443 thereof coupled to the front portion 433a of the impeller chamber 433 and a rear end 443b of the shaft 443 coupled to the rear portion 433b of the impeller chamber 433. More specifically, a front end 443a of the shaft 443 of the impeller 440 is inserted into a hub 484 in a front support 444, as shown FIG. 5. The front support 444 is coupled to the walls of the impeller chamber 433. Thus, when the front end 443a is engaged by the front support 444, the front support 444 supports the shaft 443 relative to the impeller chamber 433. Similarly, the rear end 443b of the shaft 443 is inserted into and engaged by a rear support 451 of the rear portion 433b of the impeller chamber, as shown in FIG. 5. In particular, an adjustment mechanism 436 is used to couple the shaft 443 to the rear support 451. The adjustment mechanism 436 comprises a nut 436a, a set screw 436b of the shaft 443, and a socket 436c in the end of the shaft 443. The nut 436a is attached to a nut holding portion 453 of the rear support 451 and receives the set screw 436b such that rotation of the shaft 443 relative to nut 436a causes shaft 443 to translate relative to rear support 451. Socket 436c receives a tool to allow rotation of the shaft 443 in this manner.

As shown in FIGS. 4 and 5, the rear support 451 comprises a cylinder 452 encircling the bore 450, a nut holding portion 453 coupled to one end of the cylinder 452, and attachment portions 454 that extend radially from the cylinder 452 to couple the cylinder 452 to the engagement portion 455. Although not visible in the figures, the attachment portions 454 are arranged so as to not block the flow of liquid through the chamber 433, with the liquid flowing through the space between the engagement portion 455 and the cylinder 452 and around the attachment portions 454.

The impeller chamber 433 is also coupled to various support structures and/or comprises various surfaces that form part of the housing 410 and which facilitate joining of the other subassemblies together. For example, as shown in FIG. 4, the rear portion 433b comprises fastener holders 459 with holes 458 to receive fasteners 477. As shown in FIGS. 3 and 4 the front portion 433a comprises holes 437, and when the front portion 433a and rear portion 433b are coupled together the holes 437 align with the holes 458. Thus, as shown in FIG. 3 a fastener 477 is inserted through the holes 437 and 458 to secures the front portion 433a and rear portion 433b in the coupled state. In addition, as shown in FIG. 4, the rear portion 433b also comprises holes 457, which receive fasteners 479, as shown in FIG. 3. Similarly, the front portion 433a comprises holes 485, as shown in FIG. 4, to receive fasteners 479, as shown in FIG. 3. These fasteners 479 are used to couple the various subassemblies together, as will be described below. In some examples, the front portion 433a may also comprise holes 481, which may be used to fill the pump 400 with epoxy after assembly to make the pump 400 water resistant and also to aid with transfer of heat from pump 400 components into the coolant by removing air gaps. Furthermore, the impeller chamber 433 is coupled to housing portions 410i, 410j, 410k, and 410L.

The inlet subassembly 475 comprises the inlet 431 and vibration isolators 466. The outlet subassembly 476 comprises the outlet 432 and vibration isolators 466. In the illustrated example, the inlet 431 and outlet 432 comprise hose barb couplings. In other examples, other types of liquid couplings may be substituted for the hose barb couplings. The pump 400 may be coupled to another device (e.g., a chassis of a computing device that the pump 400 is disposed within) via the vibration isolators 459. The vibration isolators 459 may be rubber, silicon, or another compliant material that helps to absorb vibrations generated by the pump 400 and prevent (or reduce) the transmission of these vibrations to the device in which the pump 400 is disposed. As shown in FIG. 3, the outlet 432 comprises an engagement portion 487. This engagement portion 487 is configured to engage with an engagement portion 456 of the impeller chamber rear portion 433b, as shown in FIG. 5. As shown in FIG. 5, the outlet 432 may also comprise a outlet guide vane (OGV) 434 which includes fins 434a. The OGV 434 guides the flows of liquid as they exit the impeller chamber 433 and enter the outlet 432. This OGV 434 may help to straighten out the flows, removing or reducing some of the circumferential motion of the liquid flows, which is introduced by the rotation of the impeller 440, so that the fluid moves predominantly or only axially upon exiting outlet 432.

In addition, each of the inlet and outlet subassemblies 475 and 476 comprises portions of the housing 410. As shown in FIG. 3, the inlet and outlet subassemblies 475 and 476 may be positioned on opposite axial sides of the impeller chamber subassembly 473. Thus, during assembly of the pump 400 the inlet and outlet subassemblies 475 and 476 may be positioned as shown in FIG. 3 and then moved towards one another (along directions indicated by arrows 404 and 405) until the inlet 431 is fluidically coupled with one side of the impeller chamber 433 and the outlet 432 is fluidically coupled with the other side of the impeller chamber 433. In some examples, this assembly step may occur after the two stator subassemblies 471 and 472 have been assembled onto the impeller chamber subassembly 473. Once the inlet 431, outlet 432, and impeller chamber 433 are coupled together, they form the conduit 430 through which liquid coolant may flow along a central axis 439 thereof.

As shown in FIGS. 2 and 3, the pump 400 comprises a housing 410. This housing 410 may be made up of multiple portions that are joined together. Specifically, the subassemblies described above may comprise these portions of the housing 410. In particular, the housing 410 comprises inlet end wall portion 410a and lateral wall portions 410b and 410c coupled to inlet end wall portion 410a. These portions 410a-c are part of the inlet subassembly 475. The housing 410 further comprises outlet end wall portion 410f and lateral wall portions 410g and 410e. These portions 410e-g are part of the outlet subassembly 475. When assembled, the aforementioned portions 410a-c and 410e-g define the perimeter side walls of the housing 410. The housing 410 also comprises top portion 410d which is coupled to the first stator portion 420a and part of the first stator subassembly 471, and top portion 410h which is coupled to the second stator portion 420b and part of the second stator subassembly 472. The housing also comprises top housing portions 410i, 410j, 410k, and 410L which are coupled to the conduit 430 and are part of the impeller chamber subassembly 473. The top portions 410d, 410h, and 410i-410L form the top face of the housing 410. Note that the top face of the housing 410 is not necessarily uniform and does not necessarily fully cover all of the pump 400. For example, a top of the stator portion 420a and 420b may be exposed and approximately coplanar with the top face of the housing 410 (this may allow the height dimension of the pump 400 to be reduced to the absolute minimum possible for a given size of stator 420). Some of the housing portions may include holes 478 (only some are labeled) that are arranged to receive a fastener 479 to couple the subassemblies together. For example, in some implementations including the one illustrated in FIG. 3, the impeller chamber subassembly 473 comprises fasteners 479 in the form or pins, such as spring-biased push pins, and each of these may be inserted into holes 478 of one more the subassemblies to secure the respective subassemblies together. A single fastener 479 may be inserted through two holes 478 of two different subassemblies—for example, the fastener labeled 479′ in FIG. 3 may be inserted into the two holes labeled 478′ which are part of the stator subassembly 472 and the outlet subassembly 476. The other fasteners 479 and holes 478 may be similarly joined.

The bottom portion of the housing 410 (which is generally not visible in the figures and is not labeled herein) may be similarly constructed as the top portion thereof, and thus duplicative description of these portions is omitted.

Turning now to FIGS. 6 and 7, the stator portions 420a and 420b will be described in greater detail. Each stator portion 420a/420b comprises a stator core portion 421a/421b and wire windings 424a/424b which are wound around the stator core portion 421a/421b. The stator core portions 421a/421b may comprise a series of laminated layers of magnetically susceptible materials which are stacked along the axial direction, or it may comprise a single solid body of magnetically susceptible material. Each stator core portion 421a/421b comprises a base portion 426 and stator teeth 422/423 extending from the base portion 426. The base portion 426 is farthest from the impeller chamber 433 and is the part of the stator core portion 421a/421b around which the wire windings 424a/424b are wound. The stator teeth 422/423 extend laterally from the base portions 426 towards the impeller chamber 433.

In some examples, each stator core portion 421a/421b may be further divided into upper and lower portions (not labeled), which are initially separate but then later joined together. Each of these upper or lower portions comprises one of the teeth 422 or 423 and part of the base portion 426.

As shown in FIG. 6, the stator core formed by the combination of the two stator core portions 421a and 421b has a generally rectangular profile in a lateral cross-section. This profile can allow for the pump 400 to have a very convenient form factor suitable for various applications in which other pumps might not work, such as in the space constrained confines inside an information processing device. However, this profile of the stator core can give rise to challenges with the arrangement of the stator teeth 422/423, as described above. To address some of these challenges, the stator 420 comprises heterogenous teeth with different cross-sectional profiles, namely a set of first teeth 422 having a first profile shape and a set of second teeth 423 having a second profile shape.

FIG. 6, each of the stator core portions 421a and 421b comprises one first tooth 422 and one second tooth 423. The first and second teeth 422/423 are distributed circumferentially around the central axis 439, with the first and second teeth 422/423 alternating. Thus, the first tooth 422 of the stator core portion 421a is disposed diametrically opposite from the first tooth 422 of the stator core portion 421b, and similarly the second tooth 423 of the stator core portion 421a is disposed diametrically opposite from the second tooth 423 of the stator core portion 421b.

As shown in FIG. 6 each of the first teeth 422 comprises a proximal portion 422p and a distal portion 422d. The proximal portion 422p is coupled to the base 426 and extends laterally from the base 426 towards the impeller chamber 433. The distal portion 422d is coupled to the proximal portion 422p and is disposed adjacent to the impeller chamber 433. An approximate boundary between each proximal portion 422p and the connected distal portion 422d is shown in dashed lines in FIG. 6.

As shown in FIGS. 6 and 7, the distal portion 422d of each first tooth 422 has the general shape of a curvilinear triangle with blunted corners, including: a straight vertical edge 427v, a straight horizontal edge 427h at a right angle to the vertical edge 427v, and a convex curved edge 427c extending between the vertical edge 427v and the horizontal edge 427c. In this example, the curved edge 427c of each first tooth 422 is joined indirectly with the horizontal edge 427h via a corner segment 413h at a blunted corner 411h. Similarly, the curved edge 427c of each first tooth 422 is joined indirectly with the vertical edge 427v via a corner segment 413v at a blunted corner 411v. A portion of the straight vertical edge 427v is connected to the proximal portion 422p while another portion of the straight vertical edge 427v protrudes upward or downward beyond the proximal portion 422p. In the example illustrated in FIGS. 6 and 7, the distal portion 422d and proximal portion 422p are integrally connected, meaning they are to parts of the same unitary body, and thus the connected portion of the straight vertical edge 427v is not visible as an edge; however, the location of connected portion of the straight vertical edge 427v, which corresponds to the dashed lines in FIG. 6, can be deduced by conceptually extending the protruding portion of the straight vertical edge 427v until it meets with the horizontal straight edge 427h.

As shown in FIG. 6 each of the second teeth 423 also comprises a proximal portion 423p and a distal portion 423d, similar to the first teeth 422. Like the first teeth 422, the proximal portion 423p of the second teeth 423 is coupled to the base 426 and extends laterally from the base 426 towards the impeller chamber 433, and the distal portion 423d is coupled to the proximal portion 423p and is disposed adjacent to the impeller chamber 433. A boundary between the proximal portion 423p and the connected distal portion 423d is depicted in FIG. 6 as dashed lines. Furthermore, like the first teeth 422, the distal portion 423d of each second tooth 423 has the general shape of a curvilinear triangle with blunted corners, with a straight vertical edge 428v, a straight horizontal edge 428h at a right angle to the vertical edge 428v, and a convex curved edge 428c extending between the vertical edge 428v and the horizontal edge 428c. In addition, each second tooth 423 also has blunted corners 412v and 412h, with corner segments 414v and 414h, respectively. The straight vertical edges 428v include a connected portion and a protruding portion, similar to the straight vertical edges 427v.

As shown in FIG. 7, although the shapes of the distal portions 422d/423d of the first and second teeth 422/423 both correspond generally to a curvilinear triangle with blunted corners, they nevertheless differ from one another in various respects. In particular, the distal portions 422d of the first teeth 422 have a first aspect ratio (r₁) while the distal portions 423d of the second teeth 423 have a second aspect ratio (r₂) which is different from the first aspect ratio. The aspect ratio of the distal portion 422d/423d refers to a ratio of the length of the vertical edge 427v/428v to the length of the horizontal edge 427h/428h. As shown in FIG. 7, if the lengths of the horizontal edges 427h are denoted w1, the lengths of the horizontal edges 428h are denoted w2, the lengths of the vertical edges 427v are denoted h1, and the lengths of the vertical edges 428v are denoted h2, then the aspect ratio of the distal portion 422d of the first tooth 422 is

$${r}_{1} = \frac{w 1}{h 1}$$

and the aspect ratio of the distal portion 423d of the second tooth 423 is

$${r}_{2} = \frac{w 2}{h 2} .$$

In some examples, w1 is equal to w2 but h1 is greater than h2, and thus the aspect ratios r₁ and r₂ are different. Or, to describe the same phenomenon another way, in the distal portion 423d, the location of the blunted corner 412v (i.e., the location where the curved edge 428c is joined with the vertical edge 428v via the corner segment 414v) is positioned a distance x2 from the central lateral axis 499 of the pump 400, whereas the location of the blunted corner 411v (i.e., the location where the curved edge 427c is joined with the vertical edge 427v via the corner segment 413v) is positioned a distance x1 from the central lateral axis 499, wherein x1<x2. In addition to having different aspect ratios, the distal portions 422d and 423d

differ in shape from one another in that certain corners thereof have different corner heights. Corner height refers to the distance between the curved edge 427c/428c and the adjacent vertical edge 427v/428v or horizontal edge 427h/428h at the corner. (In a non-blunted or sharp corner, the corner height is zero, whereas in a blunted corner the corner height is non-zero). In particular, in the distal portions 422d, a corner height at the blunted corner 411v where the curved edge 427c joins (indirectly) with the vertical edge 427v is c1, as shown in FIG. 7, but in the distal portions 423d, a corner height at the blunted corner 412v where the curved edge 428c joins (indirectly) with the vertical edge 428v is c2, wherein c2<c1.

In addition to having different aspect ratios and different corner heights, the distal portions 422d and 423d differ in shape from one another in that their curved edges 427c/428c have different curvatures than one another. For example, as shown in FIG. 7, the curved edges 427c of the distal portions 422d of the first teeth 422 may have curvatures that match a circle 418 centered at the axis 439 with a radius R. In other words, the curved edge 427c traces a path which follows or corresponds to an arc segment of the circle 418. On the other hand, the curved edges 428c of the distal portions 423d of the second teeth 423 may have curvatures that match an ellipse 419 centered at the axis 439 with a semi-minor axis equal to R and a semi-major axis which is greater than R. In other words, the curved edge 428c traces a path which follows or corresponds to an arc segment of the ellipse 419.

The above-described differences in shape between distal portions 422d and 423d may also be described or summarized in various other ways. For example, if radial line segments are drawn from the axis 439 to the end points of the curved edge 427c and 428c, such as the line segments r₁, r₂, r₃, r₄, in FIG. 7, then the angles between these line segments will differ as between the distal portions 422d and 423d. More specifically, an angle α between the line segments r₁ and r₂ may be greater than an angle β between the line segments r₃ and r₄. In other words, the curved edge 427c sweeps out a greater angle, and has a greater arc length, than the curved edge 428c. Moreover, an angle φ between the central lateral axis 499 and the line segment r₂ may be smaller than the angle θ between the central lateral axis 499 and the line segment r₃. In other words, the corner 411v is closer to the axis 499 than is the corner 412v not only in distance along a straight line, but also in terms of their angular position. Moreover, the length of the line segment r2 may be less than the length of the line segment r3.

The differences in shape between the distal portions 422d and the distal portions 423d results in the stator core of the stator 420 having an asymmetrical shape. Specifically, the stator 420 is asymmetric in a lateral cross-section, which refers to a cross-section taken in a plane perpendicular to the axis 439 (such as the cross-section in FIGS. 6 and 7). In particular, in the lateral cross-section, the stator 420 is asymmetrical about the central vertical axis 498 and about the central lateral axis 499. Note that stator 420 may be symmetric when considered in other cross-sections or about other axes.

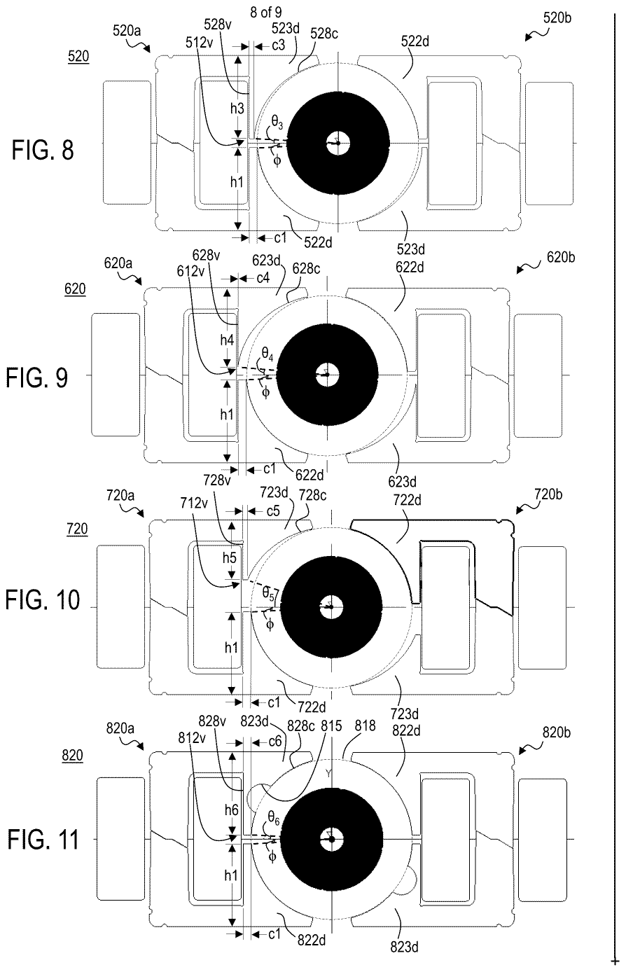

It is noted that the differences described above are interrelated, and the varying of one of the described parameters may affect another. For example, if the length of the vertical edge 428v is changed, this can cause a change in the curvature of the curved edge 428c, a change in the angles β and θ, a change in the corner height of the blunted corner 412v, or any combination of these. The same may be true for changing any of the other parameters. Furthermore, it may be possible to hold one or more of the parameters fixed while changing others of the parameters in concert. For example, a curvature of the curved edge 42ic may be held fixed while changing a length of the vertical edge 428v and a corner height of the blunted corner 412v. Although FIGS. 6 and 7 show particular shapes of the distal portions 422d/423d resulting from a particular combination of these parameters, it should be understood that examples disclosed herein are not limited to just these particular values of the parameters. Other examples disclosed herein include stators having first and second teeth with distal portions whose shapes are similar to those of the distal portions 422d/423d but which vary from the distal portions 422d/423d in one or more of the above-described parameters. In other words, various examples disclosed herein include, among other things, any combination of shapes for the distal portions of the stator teeth which can be created by starting with a curvilinear triangle (with or without blunted corners) and varying any combination of the parameters described above. Various examples of shapes which can be achieved by variation in these parameters will be described below with reference to FIGS. 8-11.

FIG. 8 illustrates one example configuration of a stator 520, which could be used as the stator 120 of the pump 100, or which can be used in the pump 400 in lieu of the stator 420. The stator 520 comprises a stator portion 520a and a stator portion 520b, which may be configured similarly to the stator portions 420a and 420b described above except that some of the distal portions of the stator teeth of the stator 520 may have slightly different shapes relative to those of the stator 420.

In the stator 520, a distal portion 522d of first stator teeth may be similar in shape to the distal portion 422d of first stator teeth 422 described above. In addition, the distal portion 523d may have a similar aspect ratio as the distal portion 522d. However, a distal portion 523d may differ in shape from the distal portion 522d in that the curved edge 528c has a different curvature than the curved edge of the distal portion 522d and the corner height c3 of the corner 512v is less than the corner height c1 of the corresponding corner in the distal portion 522d. Thus, in examples, the shape of the distal portion 523d may be generated by starting with the same shape as the distal portion 522d and then changing the curvature of the curved edge 528c (e.g., expanding the semi-major axis of the ellipse that the curved edge 528c follows), which also causes a reduction in the corner height c3 of the corner 512v.

The distal portion 523d of second stator teeth may differ from the distal portion 423d of second stator teeth 423 in that the length h3 of the vertical edge 528v in the distal portion 523d may be greater than the length h2 of the vertical edge 428v in the distal portion 423d, the curvature of the curved edge 528c may differ from that of the curved edge 428c, and the angle θ₃ may be much less than the angle θ. In some examples, the corner height c3 of the blunt corner 512v may be the same as the corner height c2 of the blunt corner 412v, while in other cases it may differ slightly.

FIG. 9 illustrates another example configuration of a stator 620, which could be used as the stator 120 of the pump 100, or which can be used in the pump 400 in lieu of the stator 420. The stator 620 comprises a stator portion 620a and a stator portion 620b, which may be configured similarly to the stator portions 420a and 420b described above except that some of the distal portions of the stator teeth of the stator 620 may have slightly different shapes relative to those of the stator 420.

In the stator 620, a distal portion 622d of first stator teeth may be similar in shape to the distal portions 422d and 522d described above. However, the distal portion 623d of the second stator teeth may differ from the distal portions 423d and 523d in that the corner height c4 of the corner 612v is less than both the corner heights c2 and c3 of the corners 412v and 512v. More specifically, in the stator 620, the corner 612v is a sharp corner, meaning the corner height c4 is zero, whereas in the stators 420 and 520 the corners 412v and 512v are blunt corners with the corner heights c2 and c3 being positive. In addition, the curvature of the curved edge 528c may differ from that of the curved edges 428c and 528c. In some examples, the length h4 of the vertical edge 628v in the distal portion 623d may be different than the lengths h2 and h3, while in other examples, the lengths h4, h2, and h3 may be the same. In some examples, angle θ₄ may be equal to the angle θ₃, while in other examples, the θ₄ may differ from the angle θ₃. In some examples, the shape of the distal portion 623d may be generated by starting with the same shape as the distal portion 523d and then further changing the curvature of the curved edge 628c (e.g., further expanding the semi-major axis of the ellipse that the curved edge 628c follows), which results in further reduction in the corner height c4 until it reaches zero.

FIG. 10 illustrates another example configuration of a stator 720, which could be used as the stator 120 of the pump 100, or which can be used in the pump 400 in lieu of the stator 420. The stator 720 comprises a stator portion 720a and a stator portion 720b, which may be configured similarly to the stator portions 420a and 420b described above except that some of the distal portions of the stator teeth of the stator 720 may have slightly different shapes relative to those of the stator 420.

In the stator 720, a distal portion 722d of first stator teeth may be similar in shape to the distal portions 422d, 522d, and 622d described above. However, the distal portion 723d of the second stator teeth may differ from the distal portions 423d, 523d, and 623d in that that the length h5 of the vertical edge 728v in the distal portion 723d is less than the lengths h4, h3, and h2. In addition, the corner height c5 of the corner 712v is greater than the corner height h4. Furthermore, the curvature of the curved edge 728c differs from the curvatures of the curved edges 528c and 428c. In some examples, the curvature of the curved edge 728c may be the same as the curvature of the edge 628c. In addition, the angle θ₅ may be the greater than the angles θ, θ₃, and θ₄. In some examples, the shape of the distal portion 723d may be generated by starting with the same shape as the distal portion 622d and then cutting off the sharp corner to create a blunted corner 721v and thereby reducing the length h5 of the vertical edge 728v and increasing the size of the angle θ₅.

FIG. 10 illustrates another example configuration of a stator 820, which could be used as the stator 120 of the pump 100, or which can be used in the pump 400 in lieu of the stator 420. The stator 820 comprises a stator portion 820a and a stator portion 820b, which may be configured similarly to the stator portions 420a and 420b described above except that some of the distal portions of the stator teeth of the stator 820 may have slightly different shapes relative to those of the stator 420.

In the stator 820, a distal portion 822d of first stator teeth may be similar in shape to the distal portions 422d, 522d, 622d, and 722d described above. However, the distal portion 823d of the second stator teeth may differ from the distal portions 423d, 523d, 623d, and 723d in that a cutout feature 815 is included in the curved edge 828c of the distal portion 823d. Furthermore, the distal portion 823d has the same aspect ratio as the distal portion 822d, and the curved edge 828c has the same curvature as the curved edge of distal portion 822d (i.e., the both follow the same circle 818). In addition, the length h6 of the vertical edge 828v may be equal to the length h1, and the corner height c6 may be equal to the corner height c1. In some examples, the shape of the distal portion 823d may be generated by starting with the same shape as the distal portion 822d and then cutting out the cutout feature 815.

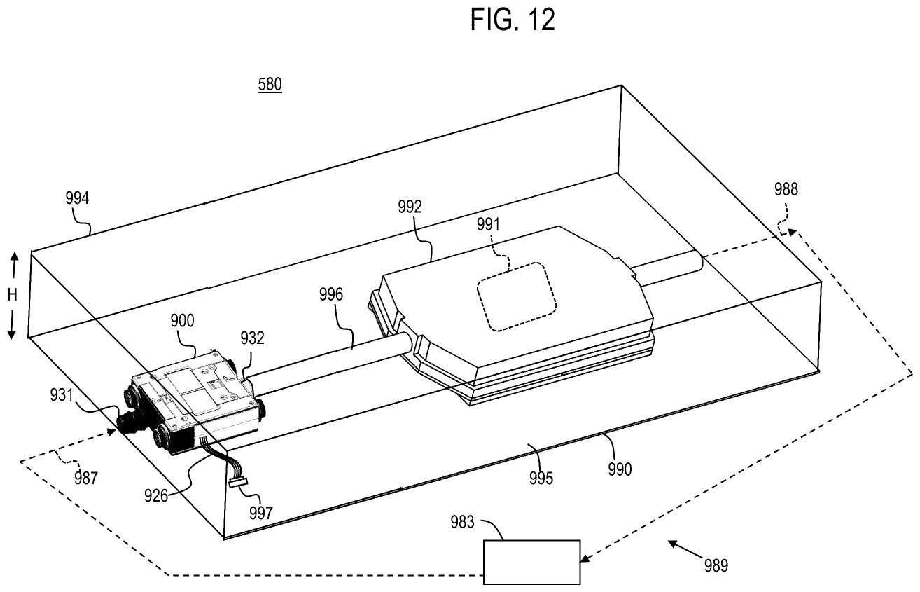

In the example of FIG. 11, the cutout feature 815 has a circular profile, with the center of the circle disposed along the line which would have been traced by the curved edge 828c absent the cutout feature 815. In other examples, other cutout features may be used which differ in size or shape from the cutout feature 815. In some examples, multiple cutout features are provided in a single curved edge, and these may be the same or vary from one another in shape and/or size. In FIG. 11, the only difference between the distal portion 822d and the distal portion 823d is the cutout features 815, but in some examples cutout features may be used in addition to other differences in shape, such as a difference in aspect ratio and/or a difference in curvature of the curved edge. For example, one or more cutout features could be added to any of the curved edges of the distal portions 423d, 523d, 623d, or 723d.

FIG. 12 comprises a schematic diagram illustrating an example system 980 and electronic device 990. The system 980 comprises the electronic device 990 and a liquid cooling loop 989 coupled to the electronic device 990. The system may also comprise additional electronic devices (not illustrated). For example the system 980 may comprise a rack or plurality of racks of electronic devices. The electronic device 990 is illustrated in a state of being installed in the system 980 for convenience of description, but it should be understood that the electronic device 990 may be provided separate from the system 980.

The liquid cooling loop 989 comprises the pump 900 (described below), one or more coolant supply lines 987, one or more coolant return lines 988, and one or more additional cooling loop components 983 such as a heat exchanger, rack-, row-, or datacenter-level coolant distribution unit(s), a chiller, or other cooling components that would be familiar to those of ordinary skill in the art.

The electronic device 990 comprises a PCB 995, such as a baseboard or motherboard of a computing device, and a chassis 994 supporting and housing the PCB 995. The PCB 995 comprises an electrical component 991, such as a processor, power supply unit, memory device, hardware accelerator, or any other electrical component. The electronic device 990 further comprises a cold plate 992 thermally coupled to the electrical component 991.

The electronic device 990 further comprises a pump 900 disposed with in the chassis 994. The pump 900 may be any of the pumps described above, such as the pump 100 and the pump 400. The pump 900 is fluidically coupled with the cold plate 992 via coolant line 996. The pump 900 is electrically connected to the PCB 995 via wires/cable connected to connector 997 of the PCB 995. Thus, the PCB 995 can supply power to and/or communicate with the pump 900. The pump 900 comprises an inlet 931 that may be coupled to the liquid coolant supply line 987 of the liquid cooling loop 989 of the system 980, which supplies liquid coolant to the pump 900. An outlet 932 of the pump 900 is coupled to the coolant line 996. An outlet of the cold plate 992 may be coupled to a liquid coolant return line 988 of the liquid cooling loop, which returns liquid coolant to the remainder of the loop for eventual cooling (e.g., at a heat exchanger). Thus, when the electronic device 990 is installed in the system 980 and fluidically coupled into the liquid cooling loop 989 thereof, liquid coolant from the loop 989 can flow through the pump 900 and cold plate 992. In particular, the pump 900 may be configured to cause (or at least contribute to) the flowing of the liquid coolant through the cold plate 992 to cool the electrical component 991.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. An axial pump for delivering liquid coolant to cool an electronic device, comprising:
a conduit defining a flow path from an inlet of the conduit to an outlet of the conduit;
an impeller in the conduit;
a shaft disposed in and coupled to the conduit;
a rotor disposed in a hollow interior of the impeller and rotatably coupled to the shaft;
a stator configured to drive rotation of the rotor about the shaft, the impeller rotating with the rotor about an axis of rotation extending parallel to the flow path
wherein the stator comprises a set of first stator teeth each having a first profile shape and a set of second stator teeth each having a second profile shape different than the first profile shape.

2. The axial pump of claim 1,
wherein the stator comprises two of the first stator teeth disposed diametrically opposite one another and two of the second stator teeth disposed diametrically opposite one another.

3. The axial pump of claim 1,
wherein the stator comprises first stator core portion and a second stator core portion disposed on diametrically opposite lateral sides of the conduit.

4. The axial pump of claim 3,
wherein the first stator core portion comprises one of the first stator teeth and one of the second stator teeth, and the second stator core portion comprises one of the first stator teeth and one of the second stator teeth.

5. The axial pump of claim 1,
wherein each of the first stator teeth and the second stator teeth comprises a distal portion disposed adjacent the conduit; and
wherein the distal portion of each of the first stator teeth has a different profile shape than the distal portion of each of the second stator teeth.

6. The axial pump of claim 5,
wherein each of the distal portions of the first and second stator teeth has a vertical edge, a horizontal edge extending perpendicularly from the vertical edge, and a concave curved edge extending between the vertical and horizontal edges.

7. The axial pump of claim 6,
wherein the curved edges of the first stator teeth differ in curvature from the curved edges of the second stator teeth.

8. The axial pump of claim 7,
wherein the curved edges of the first stator teeth have a curvature matching a circle centered at the axis of rotation, and
wherein the curved edges of the second stator teeth have a curvature matching an ellipse with non-zero eccentricity centered at the axis of rotation.

9. The axial pump of claim 6,
wherein the distal portions of the first stator teeth have a first aspect ratio; and
wherein the distal portions of the second stator teeth have a second aspect ratio, different from the first aspect ratio.

10. The axial pump of claim 9,
wherein the vertical edges of the first stator teeth are longer than the vertical edges of the second stator teeth.

11. The axial pump of claim 6,
wherein, for each of the first stator teeth, a corner where the curved edge of the respective first stator tooth joins the vertical edge thereof has a first corner height, and
wherein, for each of the second stator teeth, a corner where the curved edge of the respective second stator tooth joins the vertical edge thereof has a second corner height, different than the first corner height.

12. The axial pump of claim 6,
wherein both the first corner height and the second corner height are non-zero, the first corner height is greater than second corner height.

13. The axial pump of claim 6,
wherein the first corner height is non-zero and the second corner height is zero.

14. The axial pump of claim 6,
wherein the curved edges of the second stator teeth each includes one or more cutout features which are not present in the curved edges of the first stator teeth.

15. An electronic device, comprising:
a printed circuit board (PCB);
an electrical component coupled to the PCB;
a chassis housing the PCB;
a cold plate thermally coupled to the electrical component; and
the axial pump of claim 1 disposed within the chassis, wherein the conduit of the axial pump is fluidically coupled with the cold plate.

16. The electronic device of claim 15,
wherein the electronic device is a server and the electrical component is a processor.

17. A system, comprising:
a plurality of information processing devices, each comprising a chassis, a printed
circuit board disposed in the chassis, an electrical component coupled to the PCB, and a cold plate thermally coupled to the electrical component;
a plurality of instances of the axial pump of claim 1, wherein each of the axial pumps is disposed in the chassis of one of the information processing devices, and the respective conduits of the axial pumps are fluidically coupled with the cold plates of the information processing devices, respectively; and
a liquid cooling loop comprising liquid coolant supply lines configured to supply liquid coolant to the axial pumps, liquid coolant return lines configured to return liquid coolant from the pumps, and a heat exchanger configured to cool the liquid coolant.

18. The system of claim 17,
wherein the axial pumps are individually controllable to individually adjust the flow rate of the liquid coolant through the information processing devices.

19. A method of manufacturing an axial pump, comprising:
providing a conduit with an impeller/rotor subassembly contained within the conduit with an axis of rotation of the impeller/rotor subassembly being coaxial with a flow direction of liquid through the conduit;
disposing a first stator portion on a first lateral side of the conduit and disposing a second stator portion on a second lateral side of the conduit diametrically opposite the first stator portion,
wherein each of the first and second stator portions comprises: a first stator tooth having a first profile shape and a second stator tooth having a second profile shape different than the first profile shape.

20. The method of claim 19,
wherein disposing the first stator portion on the first lateral side of the conduit comprises disposing distal portions of the first tooth and the second tooth of the first stator portion adjacent the conduit,
wherein disposing the second stator portion on the second lateral side of the conduit comprises disposing distal portions of the first tooth and the second tooth of the second stator portion adjacent the conduit,
wherein the respective distal portions of the first stator teeth have a different profile shape than the respective distal portions of the second stator teeth.
